(19) United States
(12) Patent Application Publication
(10) Pub. No.: US 2015/0194217 A1
(43) Pub. Date: Jul. 9, 2015

(54) METHOD OF CONTROLLING MEMORY ARRAY

(71) Applicant: Shanghai Huahong Grace Semiconductor Manufacturing Corporation, Shanghai (CN)

(72) Inventors: Jing Gu, Shanghai (CN); Yongfu Zhang, Shanghai (CN)

(21) Appl. No.: 14/579,368

(22) Filed: Dec. 22, 2014

(30) Foreign Application Priority Data
Jan. 9, 2014 (CN) 201410010434.X

(51) Int. Cl. G11C 16/14; G11C 16/26

(52) U.S. Cl. CPC G11C 16/14; G11C 16/26

(57) ABSTRACT

A method of controlling a memory array is provided. The memory array includes memory cells, first control lines, second control lines, parallel bit lines and word lines that are perpendicular to the bit lines and are electrically insulated therefrom. The method includes selecting one or more of the memory cells and enabling a reading, a programming or an erasing operation on the selected memory cell(s) by applying different voltages respectively to word line(s), first control line(s) and second control line(s), connected to the selected memory cell(s), bit line(s) connected to source(s) of the selected memory cell(s) and bit line(s) connected to drain(s) of the selected memory cell(s), wherein the remaining one(s) of the first and second control line(s) that are connected to the unselected one(s) of the memory cell(s), is applied with a minus voltage ranging from −3 V to −0.5 V.

### CROSS-REFERENCES TO RELATED APPLICATIONS

This application claims the priority of Chinese patent application number 201410010434.X, filed on Jan. 9, 2014, the entire contents of which are incorporated herein by reference.

### TECHNICAL FIELD

The present invention relates generally to semiconductor technology, and in particular, to a method of controlling a memory array.

### BACKGROUND

Since the advent of storage technology, there have been developed many types of memory devices, including: random access memories (RAMs), read-only memories (ROMs), dynamic random access memories (DRAMs), erasable programmable read-only memories (EPROMs), electrically erasable programmable read-only memories (EEPROMs) and flash memories.

In these memory devices, flash memories are a type of non-volatile storage media and have been extensively used in mobile phones, computers, personal digital assistants (PDAs), digital cameras, U disks and other mobile and communication devices thanks to their perceived advantages such as ease-to-use, high storage density and high reliability.

Like other semiconductor memory devices, a flash memory also includes a memory array and peripheral circuitry. The memory array includes a number of memory cells, arranged in an array and each including a control gate and a floating gate. The control gate is connected to a control line and the floating gate is configured to retain electric charges. Memory cells in the same row commonly use the same word line, while memory cells in the same column commonly use the same bit line. When a word line is applied with a voltage and memory cells in a corresponding row are thereby selected, further applying voltages to corresponding bit lines can effectively narrow the selection to target memory cells. At the same time, the other memory cells sharing the same bit lines as the target memory cells are not selected as their corresponding word lines are not energized. Likewise, the selected memory cells other than the target ones in the same row corresponding to the energized word line are not ultimately selected because their corresponding bit lines are not energized. In general, the word and control lines corresponding to the unselected memory cells all have a voltage of 0 V. In this way, by applying different voltages to corresponding control, bit and word lines, reading, programming and erasing operations are enabled to be performed on the target memory cells.

However, during the aforementioned operations, there are typically voltage differentials between the bit lines, which tend to drive electrons into floating gates of unintended memory cells and hence turn their state from “erased” to “programmed”. Such undesired effect is referred to as electron crosstalk.

Therefore, there is an urgent need in this art for a solution to address the problem of electron crosstalk between target and unintended memory cells arising during the operations of the conventional memory arrays.

### SUMMARY OF THE INVENTION

It is an objective of the present invention to provide such a solution to address the problems encountered in the conventional memory arrays.

In accordance with this objective, the present invention provides a method of controlling a memory array. The memory array includes a plurality of memory cells each including a source, a drain and a gate, a plurality of first control lines, a plurality of second control lines, a plurality of bit lines arranged in parallel to one another and a plurality of word lines crossing the plurality of bit lines at right angles and electrically insulated therefrom. The method comprises: selecting one or more of the plurality of memory cells and performing a reading, a programming or an erasing operation on the selected one or more of the plurality of memory cells by applying different voltages respectively to one of the plurality of word lines, one of the plurality of first control lines and one of the plurality of second control lines, that are connected to each of the selected one or more of the plurality of memory cells, one of the plurality of bit lines connected to the source of and one of the plurality of bit lines connected to the drain of each of the selected one or more of the plurality of memory cells, wherein each of the remaining ones of the plurality of first and second control lines that are connected to the unselected ones of the plurality of memory cells, is applied with a minus voltage ranging from −3 V to −0.5 V.

Preferably, when a reading operation is performed, a first voltage Vwln-r, a second voltage Vcgn-1-r, a third voltage Vcgn-2-r, a fourth voltage Vbl2+1-r and a fifth voltage Vbl2+2-r are respectively applied to the one of the plurality of word lines, the one of the plurality of first control lines and the one of the plurality of second control lines, connected to each of the selected one or more of the plurality of memory cells, the one of the plurality of bit lines connected to the source of and the one of the plurality of bit lines connected to the drain of each of the selected one or more of the plurality of memory cells; and the first voltage Vwln-r, second voltage Vcgn-1-r, third voltage Vcgn-2-r, fourth voltage Vbl2+1-r and fifth voltage Vbl2+2-r are in ranges of 0.5-5 V, 0-3 V, 0-6 V, 0-0.5 V and 0.8-3 V, respectively.

More preferably, the first voltage Vwln-r, second voltage Vcgn-1-r, third voltage Vcgn-2-r, fourth voltage Vbl2+1-r and fifth voltage Vbl2+2-r are 2.5 V, 2.5 V, 4 V, 0 V and 2 V, respectively.

Preferably, when a programming operation is performed, a sixth voltage Vwln-p, a seventh voltage Vcgn-1-p, an eighth voltage Vcgn-2-p, a ninth voltage Vbl2+1-p and a tenth voltage Vbl2+2-p are respectively applied to the one of the plurality of word lines, the one of the plurality of first control lines and the one of the plurality of second control lines, connected to each of the selected one or more of the plurality of memory cells, the one of the plurality of bit lines connected to the source of and the one of the plurality of bit lines connected to the drain of each of the selected one or more of the plurality of memory cells; and the sixth voltage Vwln-p, seventh voltage Vcgn-1-p, eighth voltage Vcgn-2-p, ninth voltage Vbl2+1-p and tenth voltage Vbl2+2-p are in ranges of 1.0-2 V, 5-11 V, 2-6 V, 2.5-6 V and 0-0.6 V, respectively.

More preferably, the sixth voltage Vwln-p, seventh voltage Vcgn-1-p, eighth voltage Vcgn-2-p, ninth voltage Vbl2+1-p and tenth voltage Vbl2+2-p are 1.5 V, 8 V, 5 V, 5.5 V and Vdp, respectively, where Vdp is a constant programming voltage ranging from 0.2 V to 0.6 V.

Preferably, when an erasing operation is performed, an eleventh voltage Vwln-e, a twelfth voltage Vcgn-1-e, a thirteenth voltage Vcgn-2-e, a fourteenth voltage Vbl2+1-e and a fifteenth voltage Vbl2+2-e are respectively applied to the one of the plurality of word lines, the one of the plurality of first control lines and the one of the plurality of second control lines, connected to each of the selected one or more of the plurality of memory cells, the one of the plurality of bit lines connected to the source of and the one of the plurality of bit lines connected to the drain of each of the selected one or more of the plurality of memory cells; and the eleventh voltage Vwln-e, twelfth voltage Vcgn-1-e, thirteenth voltage Vcgn-2-e, fourteenth voltage Vbl2+1-e and fifteenth voltage Vbl2+2-e are in ranges of 5-10 V, −10-−5 V, −b10-−5 V, 0-0.5 V and 0-0.5 V, respectively.

More preferably, the eleventh voltage Vwln-e, twelfth voltage Vcgn-1-e, thirteenth voltage Vcgn-2-e, fourteenth voltage Vbl2+1-e and fifteenth voltage Vbl2+2-e are 8 V, −7 V, −7 V, 0 V and 0 V, respectively.

Preferably, the plurality of memory cells are arranged in an array in which ones of the plurality of memory cells in a same row commonly use a same one of the plurality of word lines and ones of the plurality of memory cells in a same column commonly use a same one of the plurality of bit lines; each of the plurality of bit lines connects a source of a corresponding one of the plurality of memory cells and a drain of an adjacent one of the plurality of memory cells, and a portion of a corresponding one of the plurality of word lines located between two adjacent ones of the plurality of memory cells connects gates of the two adjacent ones of the plurality of memory cells; each of the plurality of memory cells includes a first storage cell and a second storage cell, the first storage cell located between a corresponding one of the plurality of word lines and a source of the particular one of the plurality of memory cells, the second storage cell located between the corresponding one of the plurality of word lines and a drain of the particular one of the plurality of memory cells; the first storage cell includes a first control gate and a first floating gate and the second storage cell includes a second control gate and a second floating gate; the first control gate is arranged above the first floating gate and the second control gate is arranged above the second floating gate; the first control gate is connected to a corresponding one of the plurality of first control lines and the second control gate is connected to a corresponding one of the plurality of second control lines; and each of the plurality of first control lines and a corresponding one of the plurality of second control lines, that both connect ones of the plurality of memory cells in the same row, are located on opposing sides of a corresponding one of the plurality of word lines.

As described above, by applying a minus voltage to first and second control lines connecting memory cell(s) whose word line(s) are unselected so as to prevent electrons from being driven into unselected memory cell(s) by voltage differential(s) between the corresponding bit lines, the method of the present invention ensures that no electron crosstalk will occur with the unselected memory cells when a desired operation is performed on selected memory cell(s).

### BRIEF DESCRIPTION OF DRAWINGS

FIG. 1 depicts a schematic illustration of a memory array in accordance with an embodiment of the present invention.

FIG. 2 is depicts a circuit diagram of the memory array in accordance with the embodiment of the present invention.

FIG. 3 depicts an enlarged schematic view of a memory cell in the memory array in accordance with the embodiment of the present invention.

### DETAILED DESCRIPTION

The method of the present invention will be described in greater detail with reference to the following description of exemplary embodiments, taken in conjunction with the accompanying drawings. Features and advantages of the invention will be apparent from the following detailed description, and from the claims. It is noted that all the drawings are presented in a very simple form and not drawn precisely to scale. They are provided solely to facilitate the description of the exemplary embodiments in a convenient and clear way.

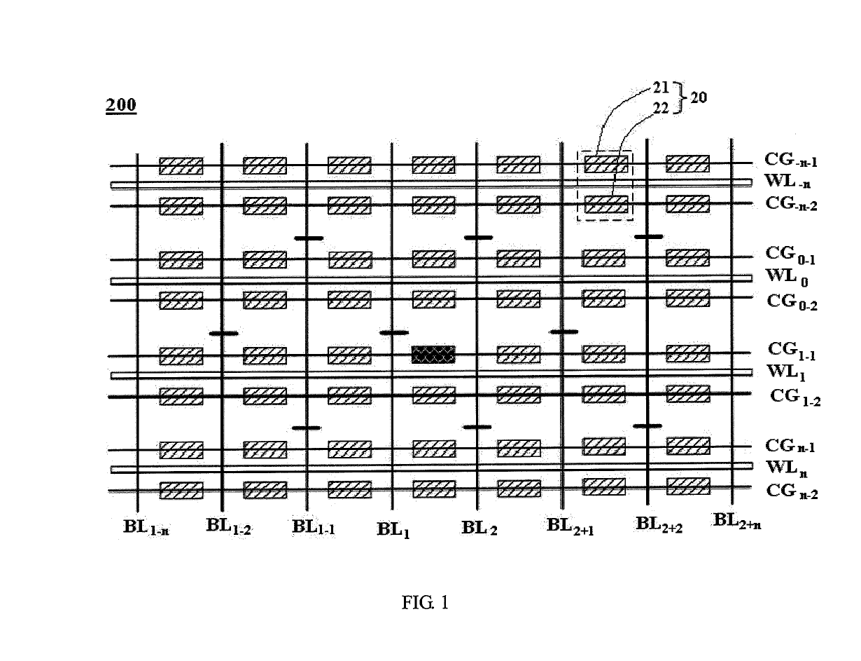

FIG. 1 schematically illustrates a memory array 200 in accordance with an embodiment of the present invention. As illustrated, the method of the present invention for controlling the memory array 200 includes allowing a reading, programming or erasing operation to be performed on target memory cell(s), i.e. selected memory cell(s), of the memory array 200 by applying different voltages respectively to word line(s), first control line(s) and second control line(s), connected to the target memory cell(s), bit line(s) connected to source(s) of the target memory cell(s) and bit line(s) connected to drain(s) of the target memory cell(s), wherein the other first control line(s) and the other second control line(s), connected to the unselected memory cell(s) other than the target one(s) in the memory array 200, are all applied with a minus voltage.

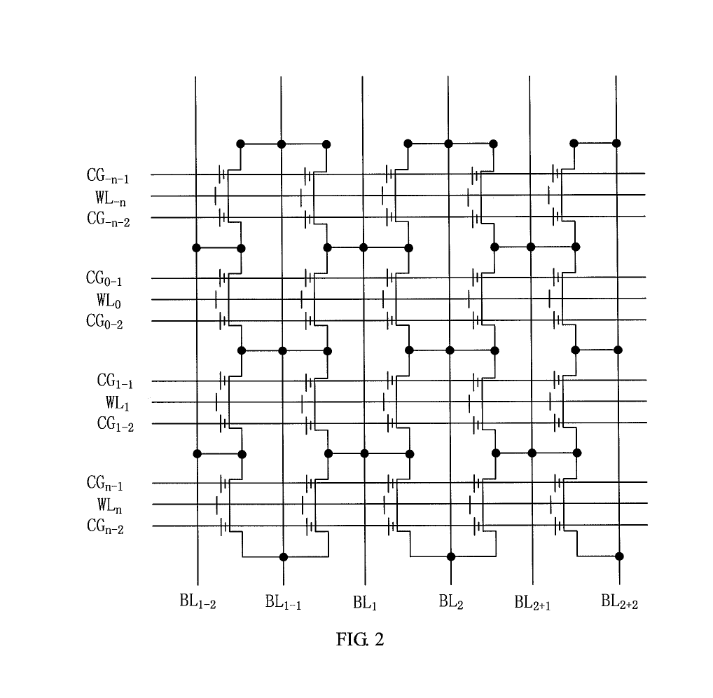

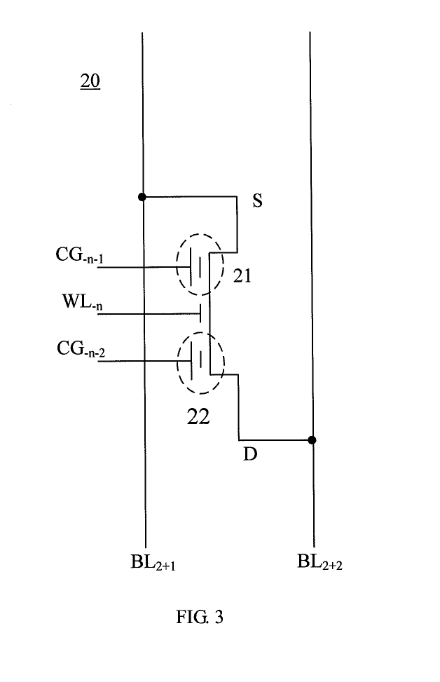

Specifically, with additional reference to FIG. 2 that is a circuit diagram of the memory array 200 and FIG. 3 that is an enlarged schematic view of a memory cell 20 in the memory array 200, the memory array 200 includes a plurality of memory cells 20, a plurality of first control lines, a plurality of second control lines, a plurality of bit lines arranged in parallel, and a plurality of word lines that are perpendicular to and electrically insulated from the bit lines. The memory cells 20 are arranged in an array and each of the memory cells 20 includes a gate G, a source S and a drain D. The word lines, first control lines and second control lines all extend in a row direction, while the bit lines extend in a column direction, of the memory array 200. The bit lines are parallel to one another and cross the word lines at right angles and are electrically insulated from the word lines. Each of the memory cells 20 has its source S connected to one of corresponding two adjacent bit lines that are both connected to the particular memory cell 20 and has its drain D connected to the other of the corresponding two adjacent bit lines. Memory cells 20 in the same column commonly use the same bit line which is also commonly used by drains D of memory cells of an adjacent column. Memory cells 20 in the same row commonly use the same word line, and portions of the word line between bit lines connect gates of the memory cells 20, i.e., each word line connect gates of all memory cells in a corresponding row along the row direction of the memory array 200.

Preferably, on each of the bit lines, sources S and drains D of memory cells 20 that are connected to the particular bit line are formed, and portions of each word line forms gates G of memory cells 20 that are connected to the particular word line.

With continuing reference to FIGS. 1 to 3, each of the memory cells 20 includes a first storage cell 21 and a second storage cell 22. The first storage cell 21 is located between a corresponding word line and a source of the particular memory cell 20, while the second storage cell 22 is located between the word line and a drain of the particular memory cell 20. The first storage cell 21 includes a gate structure (not shown) that further includes a first control gate and a first floating gate. Likewise, the second storage cell 22 includes a gate structure (not shown) that further includes a second control gate and a second floating gate. The first control gate is formed above the first floating gate, and the second control gate is formed above the second floating gate. The first control gate of the first storage cell 21 is connected to a corresponding first control line, and the second control gate of the second storage cell 22 is connected to a corresponding second control line. Each first control line and a corresponding second control line, that both connect to the memory cells 20 of the same row, are located on opposite sides of a corresponding word line and in parallel thereto. Each of the memory cell 20 may be implemented as a structure described in U.S. Pat. No. 8,693,243 that is assigned to the applicant of the present invention and is incorporated herein by reference in its entirety.

As shown in FIG. 1, memory cells 20 in the same row include a row of first storage cell 21 and a row of second storage cell 22, that commonly use the same word line located therebetween.

In the memory array 200, each memory cell 20 may have only one of its storage cells, i.e., first storage cell 21 or second storage cell 22, in use and have the other one of the storage cells, i.e., second storage cell 22 or first storage cell 21, kept idle. This can make the memory cells 20 more durable.

A reading, programming or erasing operation is possible to be performed on target memory cell(s) 20 of the memory array 200, when word line(s), first control line(s) and second control line(s), connected to the target memory cell(s) 20, bit line(s) connected to source(s) S of the target memory cell(s) 20 and bit line(s) connected to drain(s) D of the target memory cell(s) 20 are applied with respective voltages.

When a reading operation is performed on the memory array 200, a first voltage Vwln-r, a second voltage Vcgn-1-r, a third voltage Vcgn-2-r, a fourth voltage Vbl2+1-r and a fifth voltage Vbl2+2-r may be applied to the word line(s), the first control line(s) and the second control line(s), connected to the target memory cell(s) 20, the bit line(s) connected to the source(s) S of the target memory cell(s) 20 and the bit line(s) connected to the drain(s) D of the target memory cell(s) 20. The first voltage Vwln-r, second voltage Vcgn-1-r, third voltage Vcgn-2-r, fourth voltage Vbl2+1-r and fifth voltage Vbl2+2-r may be in ranges of 0.5-5 V, 0-3 V, 0-6 V, 0-0.5 V and 0.8-3 V, respectively, with 2.5 V, 2.5 V, 4 V, 0 V and 2 V, respectively, being preferred.

As shown in FIG. 1, in one embodiment, when a word line WL₁ is applied with a voltage of 2.5 V, thereby selecting memory cells 20 of a corresponding row (in this embodiment, the block with crosses in FIG. 1 represents a target memory cell 20 to be read), corresponding bit lines BL₁ and BL₂ with voltages of 0 V and 2 V, respectively, corresponding first and second control lines CG₁₋₁ and CG₁₋₂ with voltages of 2.5 V and 4 V, respectively, a bit line BL₂₊₁ that is adjacent to the bit line BL₂ with a voltage of 2 V, and all the other bit lines with a voltage of 0 V, the target memory cell is in a readable state. While it has been described in this embodiment that the reading operation is performed on only one memory cell, the present invention is not limited in this regard as the operation may also be performed on more than one memory cell without departing from the scope of the invention.

In the foregoing state of the memory cell 20, there are voltage differentials between the bit lines. In order to prevent the voltage differentials from driving electrons into unselected memory cell(s) 20 and hence cause an electron crosstalk effect, each of the remaining ones of the first and second control lines that are connecting to the unselected ones of the memory cells 20, is provided with a minus voltage which is capable of blocking electrons from entering a floating gate and generally ranges from −3 V to −0.6 V.

Therefore, during the reading operation, the word line WL₁, first control line CG₁₋₁, second control line CG₁₋₂, bit line BL₁ connected to a source of the target memory cell 20 and bit line BL₂ connected to a drain of the target memory cell 20 have voltages of 2.5 V, 2.5 V, 4 V, 0 V and 2 V, respectively, all the other word lines WL₋ₙ, WL₀ and WLₙ have a voltage of 0 V, and all the other control lines CG₋ₙ₋₁, CG₋ₙ₋₂, CG₀₋₁, CG₀₋₂, CGₙ₋₁, and CGₙ₋₂ have a minus voltage ranging from −3 V to −0.6 V.

When a programming operation is performed on the memory array 200, a sixth voltage Vwln-p, a seventh voltage Vcgn-1-p, an eighth voltage Vcgn-2-p, a ninth voltage Vbl2+1-p and a tenth voltage Vbl2+2-p may be applied to the word line(s), the first control line(s) and the second control line(s), connected to the target memory cell(s) 20, the bit line(s) connected to the source(s) S of the target memory cell(s) 20 and the bit line(s) connected to the drain(s) D of the target memory cell(s) 20. The sixth voltage Vwln-p, seventh voltage Vcgn-1-p, eighth voltage Vcgn-2-p, ninth voltage Vbl2+1-p and tenth voltage Vbl2+2-p may be in ranges of 1.0-2 V, 5-11 V, 2-6 V, 2.5-6 V and 0-0.6 V, respectively, with 1.5 V, 8 V, 5 V, 5.5 V and Vdp, respectively, being preferred, where Vdp is a constant programming voltage ranging from 0.2 V to 0.6 V.

As shown in FIG. 1, in one embodiment, when the word line WL₁ is applied with a voltage of 1.5 V, thereby selecting the corresponding row of memory cells 20 (in this embodiment, the block with crosses in FIG. 1 represents a target memory cell 20 to be programmed), the bit lines BL₁ and BL₂ with voltages of 5.5 V and Vdp, respectively, the first and second control lines CG₁₋₁ and CG₁₋₂ with voltages of 8 V and 5 V, respectively, the bit line BL₂₊₁ that is adjacent to the bit line BL₂ with the voltage Vdp, where Vdp is a constant programming voltage generally ranging from 0.2 V to 0.6 V, the bit line BL₂₊₂ that is adjacent to the bit line BL₂₊₁ with the voltage of 1.5 V, and all the other bit lines with a voltage of 2.5 V, the target memory cell is in a programmable state. While it has been described in this embodiment that the programming operation is performed on only one memory cell, the present invention is not limited in this regard as the operation may also be performed on more than one memory cell without departing from the scope of the invention.

In the foregoing state of the memory cell 20, there are also voltage differentials between the bit lines that peak between the bit lines BL₁ and BL₂. In order to prevent the voltage differentials from driving electrons into unselected memory cell(s) 20 and hence cause an electron crosstalk effect, each of the remaining ones of the first and second control lines that are connecting to the unselected ones of the memory cells 20, is provided with a minus voltage which is capable of blocking electrons from entering a floating gate and generally ranges from −3 V to −0.6 V.

Therefore, during the programming operation, the word line WL₁, first control line CG₁₋₁, second control line CG₁₋₂, bit line BL₁ and bit line BL₂ have voltages of 1.5 V, 8 V, 5 V, 5.5 V and Vdp, respectively, all the other word lines WL₋ₙ, WL₀ and WLₙ have a voltage of 0 V, and all the other control lines CG₋ₙ₋₁, CG₋ₙ₋₂, CG₀₋₁, CG₀₋₂, CGₙ₋₁, and CGₙ₋₂ have a minus voltage ranging from −3 V to −0.6 V.

When an erasing operation is performed on the memory array 200, an eleventh voltage Vwln-e, a twelfth voltage Vcgn-1-e, a thirteenth voltage Vcgn-2-e, a fourteenth voltage Vbl2+1-e and a fifteenth voltage Vbl2+2-e may be applied to the word line(s), the first control line(s) and the second control line(s), connected to the target memory cell(s) 20, the bit line(s) connected to the source(s) S of the target memory cell(s) 20 and the bit line(s) connected to the drain(s) D of the target memory cell(s) 20. The eleventh voltage Vwln-e, twelfth voltage Vcgn-1-e, thirteenth voltage Vcgn-2-e, fourteenth voltage Vbl2+1-e and fifteenth voltage Vbl2+2-e may be in ranges of 5-10 V, −10-−5 V, −10-−5 V, 0-0.5 V and 0-0.5 V, respectively, with 8 V, −7 V, −7 V, 0 V and 0 V, respectively, being preferred.

As shown in FIG. 1, in one embodiment, when the word line WL₁ is applied with a voltage of 8 V, thereby selecting the corresponding row of memory cell 20 (in this embodiment, the block with crosses in FIG. 1 represents a target memory cell 20 to be erased), the bit lines BL₁ and BL₂ both with a voltage of 0 V, the first and second control lines CG₁₋₁ and CG₁₋₂ also both with a voltage of 0 V, and all the other bit lines also with a voltage of 0 V, the target memory cell is in an erasable state. While it has been described in this embodiment that the erasing operation is performed on only one memory cell, the present invention is not limited in this regard as the operation may also be performed on more than one memory cell without departing from the scope of the invention.

In the foregoing state of the memory cell 20, there is no voltage differential between the bit lines. Each of the remaining ones of the first and second control lines that are connecting to the unselected ones of the memory cells 20 may be either provided with a voltage of 0 V or a minus voltage ranging from −3 V to −0.6 V.

Therefore, during the erasing operation, the word line WL₁, first control line CG₁₋₁, second control line CG₁₋₂, bit line BL₁ and bit line BL₂ have voltages of 8 V, −7 V, −7 V, 0 V and 0 V, respectively, all the other word lines WLₙ, WL₀ and WLₙ have a voltage of 0 V, and all the other control lines CG₋ₙ₋₁, CG₋ₙ₋₂, CG₀₋₁, CG₀₋₂, CGₙ₋₁, and CGₙ₋₂ have a voltage of 0 V or a minus voltage ranging from −3 V to −0.6 V.

In summary, during any of the aforementioned operations, expect those connecting the memory cells in the row corresponding to the selected word line, all the other control lines, including both first and second control lines, connecting the other memory cells may be provided with a minus voltage which can block electrons from being driven into the floating gate of any unintended memory cell. As a result, no unintended memory cell will undergo a state change even when there are voltage differentials between the bit lines, thus ensuring no occurrence of electron crosstalk with unintended memory cells when a desired operation is being performed on the target memory cell.

Thus, by applying a minus voltage to first and second control lines connecting memory cell(s) corresponding to unselected word line(s) so as to prevent electrons from being driven into unintended memory cell(s) by voltage differential(s) between bit lines, the method of the present invention ensures that no electron crosstalk will occur with the unintended memory cells when a desired operation is performed on target memory cell(s).

While several preferred embodiment has been illustrated and described above, it should be understood that they are not intended to limit the invention in any way. It is also intended that the appended claims cover all variations and modifications made in light of the above teachings by those of ordinary skill in the art.

What is claimed is:

1. A method of controlling a memory array, the memory array including a plurality of memory cells each including a source, a drain and a gate, a plurality of first control lines, a plurality of second control lines, a plurality of bit lines arranged in parallel to one another and a plurality of word lines crossing the plurality of bit lines at right angles and electrically insulated therefrom, the method comprising: selecting one or more of the plurality of memory cells and performing a reading, a programming or an erasing operation on the selected one or more of the plurality of memory cells by applying different voltages respectively to one of the plurality of word lines, one of the plurality of first control lines and one of the plurality of second control lines, that are connected to each of the selected one or more of the plurality of memory cells, one of the plurality of bit lines connected to the source of and one of the plurality of bit lines connected to the drain of each of the selected one or more of the plurality of memory cells,
Wherein each of the remaining ones of the plurality of first and second control lines that are connected to the unselected ones of the plurality of memory cells, is applied with a minus voltage ranging from −3 V to −0.5 V.

2. The method of claim 1, wherein when a reading operation is performed, a first voltage Vwln-r, a second voltage Vcgn-1-r, a third voltage Vcgn-2-r, a fourth voltage Vbl2+1-r and a fifth voltage Vbl2+2-r are respectively applied to the one of the plurality of word lines, the one of the plurality of first control lines and the one of the plurality of second control lines, connected to each of the selected one or more of the plurality of memory cells, the one of the plurality of bit lines connected to the source of and the one of the plurality of bit lines connected to the drain of each of the selected one or more of the plurality of memory cells; and
wherein the first voltage Vwln-r, second voltage Vcgn-1-r, third voltage Vcgn-2-r, fourth voltage Vbl2+1-r and fifth voltage Vbl2+2-r are in ranges of 0.5-5 V, 0-3 V, 0-6 V, 0-0.5 V and 0.8-3 V, respectively.

3. The method of claim 2, wherein the first voltage Vwln-r, second voltage Vcgn-1-r, third voltage Vcgn-2-r, fourth voltage Vbl2+1-r and fifth voltage Vbl2+2-r are 2.5 V, 2.5 V, 4 V, 0 V and 2 V, respectively.

4. The method of claim 1, wherein when a programming operation is performed, a sixth voltage Vwln-p, a seventh voltage Vcgn-1-p, an eighth voltage Vcgn-2-p, a ninth voltage Vbl2+1-p and a tenth voltage Vbl2+2-p are respectively applied to the one of the plurality of word lines, the one of the plurality of first control lines and the one of the plurality of second control lines, connected to each of the selected one or more of the plurality of memory cells, the one of the plurality of bit lines connected to the source of and the one of the plurality of bit lines connected to the drain of each of the selected one or more of the plurality of memory cells; and
wherein the sixth voltage Vwln-p, seventh voltage Vcgn-1-p, eighth voltage Vcgn-2-p, ninth voltage Vbl2+1-p and tenth voltage Vbl2+2-p are in ranges of 1.0-2 V, 5-11 V, 2-6 V, 2.5-6 V and 0-0.6 V, respectively.

5. The method of claim 4, wherein the sixth voltage Vwln-p, seventh voltage Vcgn-1-p, eighth voltage Vcgn-2-p, ninth voltage Vbl2+1-p and tenth voltage Vbl2+2-p are 1.5 V, 8 V, 5 V, 5.5 V and Vdp, respectively, where Vdp is a constant programming voltage ranging from 0.2 V to 0.6 V.

6. The method of claim 1, wherein when an erasing operation is performed, an eleventh voltage Vwln-e, a twelfth voltage Vcgn-1-e, a thirteenth voltage Vcgn-2-e, a fourteenth voltage Vbl2+1-e and a fifteenth voltage Vbl2+2-e are respectively applied to the one of the plurality of word lines, the one of the plurality of first control lines and the one of the plurality of second control lines, connected to each of the selected one or more of the plurality of memory cells, the one of the plurality of bit lines connected to the source of and the one of the plurality of bit lines connected to the drain of each of the selected one or more of the plurality of memory cells; and
wherein the eleventh voltage Vwln-e, twelfth voltage Vcgn-1-e, thirteenth voltage Vcgn-2-e, fourteenth voltage Vbl2+1-e and fifteenth voltage Vbl2+2-e are in ranges of 5-10 V, −10-−5 V, −10-−5 V, 0-0.5 V and 0-0.5 V, respectively.

7. The method of claim 6, wherein the eleventh voltage Vwln-e, twelfth voltage Vcgn-1-e, thirteenth voltage Vcgn-2-e, fourteenth voltage Vbl2+1-e and fifteenth voltage Vbl2+2-e are 8 V, −7 V, −7 V, 0 V and 0 V, respectively.

8. The method of claim 1, wherein:
the plurality of memory cells are arranged in an array in which ones of the plurality of memory cells in a same row commonly use a same one of the plurality of word lines and ones of the plurality of memory cells in a same column commonly use a same one of the plurality of bit lines;
each of the plurality of bit lines connects a source of a corresponding one of the plurality of memory cells and a drain of an adjacent one of the plurality of memory cells, and a portion of a corresponding one of the plurality of word lines located between two adjacent ones of the plurality of memory cells connects gates of the two adjacent ones of the plurality of memory cells;
each of the plurality of memory cells includes a first storage cell and a second storage cell, the first storage cell located between a corresponding one of the plurality of word lines and a source of the particular one of the plurality of memory cells, the second storage cell located between the corresponding one of the plurality of word lines and a drain of the particular one of the plurality of memory cells;
the first storage cell includes a first control gate and a first floating gate and the second storage cell includes a second control gate and a second floating gate;
the first control gate is arranged above the first floating gate and the second control gate is arranged above the second floating gate;
the first control gate is connected to a corresponding one of the plurality of first control lines and the second control gate is connected to a corresponding one of the plurality of second control lines; and
each of the plurality of first control lines and a corresponding one of the plurality of second control lines, that both connect ones of the plurality of memory cells in the same row, are located on opposing sides of a corresponding one of the plurality of word lines.
